(19) United States
(12) Patent Application Publication
(10) Pub. No.: US 2019/0047090 A1
(43) Pub. Date: Feb. 14, 2019

(54) LASER PROCESSING APPARATUS

(71) Applicant: SHIMADZU CORPORATION, Kyoto (JP)

(72) Inventors: Masaya SUWA, Kyoto-shi, Kyoto (JP); Junki SAKAMOTO, Kyoto-shi, Kyoto (JP)

(73) Assignee: SHIMADZU CORPORATION, Kyoto (JP)

(21) Appl. No.: 16/079,559

(22) PCT Filed: Feb. 25, 2016
(86) PCT No.: PCT/JP2016/055642

§ 371 Date: Aug. 24, 2018

(51) Int. Cl. B23K 26/362; B23K 26/08; B23K 26/142; B23K 26/402; B23K 26/70; C23C 16/455; H01S 3/067; H01L 21/02; H01L 21/67

(52) U.S. Cl. CPC B23K 26/362; B23K 26/08; B23K 26/142; B23K 26/402; B23K 2101/40; C23C 16/45519; H01S 3/067; H01L 21/02532; H01L 21/67092; B23K 26/70

(57) ABSTRACT

A laser processing apparatus is provided with: a thin dielectric film (12) formed on the surface of a substrate (11); a blue semiconductor laser (3) with a wavelength in a 400 nm-band; a semiconductor laser drive unit (4) for generating continuous wave laser light in the blue semiconductor laser (3) by driving the blue semiconductor laser (3); and irradiation units (21, 22) for irradiating a processing position for the thin dielectric film (12) with continuous wave laser light generated by the blue semiconductor laser (3).

### TECHNICAL FIELD

The present invention relates to a laser processing apparatus configured to process a thin dielectric film used as a protective film of an electronic device or an antireflection film of a solar cell by a laser.

### BACKGROUND ART

In an electronic device, when there is no protective film formed of a thin dielectric film, the operation becomes very unstable. Thus, a protective film formed of a thin dielectric film is applied to an electronic device.

In addition, in a solar cell and the like, when a thin dielectric film is used as an antireflection film, even if a refractive index on the side of a substrate is high, the reflectance can be reduced. Thus, it is necessary to form a thin dielectric film in an electronic device or a solar cell. Since a thin dielectric film formed on the top or bottom of the substrate is an insulator, it is not possible to electrically connect an electrode and the substrate. Therefore, it is necessary to process and remove the thin dielectric film and bond the substrate and the electrode.

In the related art, etching or the like is used as a method of processing a thin dielectric film. However, this method takes time and it is not possible to precisely process the thin dielectric film. Thus, the thin dielectric film is processed by a laser.

### CITATION LIST

### [Non-Patent Literature]

### [Non-Patent Literature 1]

G. Poulain et all Energy Procedia 27 (2012) 516-521

### [Non-Patent Literature 2]

Prog. Photovolt: Res. Appl/2009; 17: 127-136

### SUMMARY OF INVENTION

### Technical Problem

However, a fiber laser, a CO₂ laser, and the like have a relatively long oscillation wavelength of several tens of μm, they pass through a thin dielectric film, and the laser beam reaches a substrate. Thus, cracks may occur in the substrate due to an influence of heat due to laser irradiation and the substrate may crack.

In addition, when a laser is a short wavelength UV laser and a thin dielectric film is made of, for example, silicon nitride, since a refractive index increases at a wavelength in a 300 nm-band, the reflectance increases. Therefore, it is necessary to increase an irradiation power or it may not be possible to perform laser processing on the thin dielectric film.

In addition, in the above laser processing, generally, pulsed light is input. However, since pulsed light has a larger maximum output than continuous wave (CW) light, the substrate is likely to crack. Thus, the development of a laser processing apparatus capable of performing laser processing on only a thin dielectric film is desired.

An objective of the present invention is to provide a laser processing apparatus capable of performing laser processing on only a thin dielectric film without cracking a substrate.

### Solution to Problem

In order to address the above problem, a laser processing apparatus according to the present invention includes a thin dielectric film that is formed on a surface of a substrate; a blue semiconductor laser with a wavelength in a 400 nm-band; a semiconductor laser drive unit configured to drive the blue semiconductor laser such that a continuous wave laser beam is generated in the blue semiconductor laser; and an irradiation unit configured to emit the continuous wave laser beam generated by the blue semiconductor laser to a processing target part of the thin dielectric film.

### Advantageous Effects of Invention

According to the present invention, when a blue semiconductor laser with a wavelength in a 400 nm-band is used and a semiconductor laser drive unit drives a blue semiconductor laser, the blue semiconductor laser generates a continuous wave laser beam and an irradiation unit emits the continuous wave laser beam to a processing target part of a thin dielectric film. Then, the continuous wave laser beam is multiply reflected in the thin dielectric film, and the high energy laser beam is confined in the thin dielectric film.

Accordingly, the high energy laser beam is absorbed into the thin dielectric film and the thin dielectric film can be removed. Therefore, the thin dielectric film can be processed by a laser without cracking a substrate.

### BRIEF DESCRIPTION OF DRAWINGS

FIG. 1 is a configuration block diagram of a laser processing apparatus according to Example 1 of the present invention.

FIG. 2 shows diagrams of a removal process according to laser processing on a thin dielectric film in a laser processing apparatus of Example 1 of the present invention.

FIG. 3 is a diagram showing a refractive index of silicon nitride used in the thin dielectric film in the laser processing apparatus of Example 1 of the present invention with respect to a wavelength.

FIG. 4 is a diagram for explaining thin dielectric film removal in the laser processing apparatus of Example 1 of the present invention.

### DESCRIPTION OF EMBODIMENTS

### Example 1

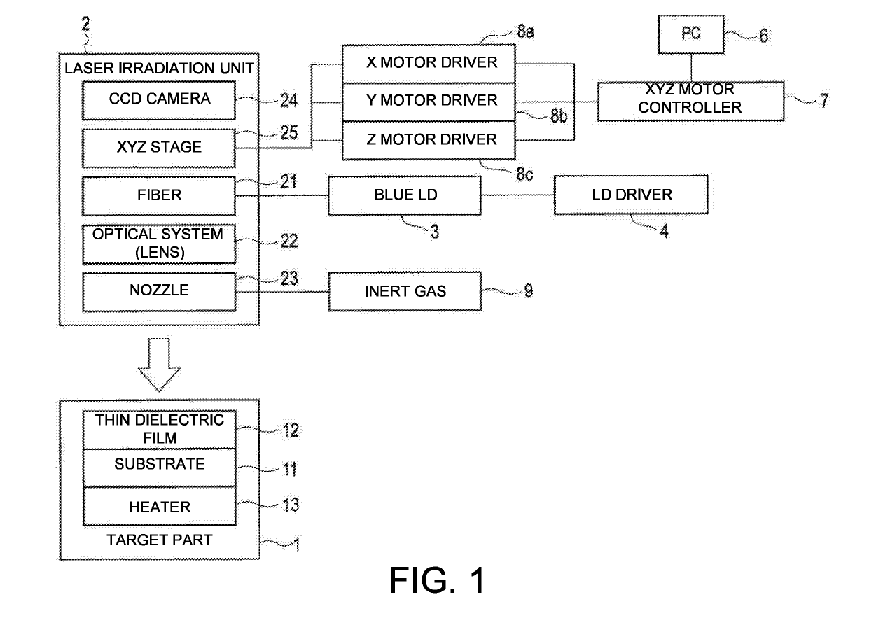

A laser processing apparatus according to an embodiment of the present invention will be described below in detail with reference to the drawings. FIG. 1 is a configuration block diagram of a laser processing apparatus of Example 1 of the present invention.

The laser processing apparatus includes a target part 1 to which a laser is emitted, a laser irradiation unit 2 configured to emit a laser to the target part 1, a blue semiconductor laser diode (hereinafter referred to as a blue LD) 3, a laser diode driver (hereinafter referred to as an LD driver) 4, a personal computer (hereinafter referred to as a PC) 6, an XYZ motor controller 7, an X motor driver 8a, a Y motor driver 8b, a Z motor driver 8c, and an inert gas 9.

In the target part 1, a substrate 11, a thin dielectric film 12 formed on an upper surface of the substrate 11, and a heater 13 that is in contact with the substrate 11 or disposed in the vicinity of the substrate 11 and heats the substrate 11 are provided. For the thin dielectric film 12, silicon nitride, silicon dioxide, titanium dioxide, or the like is used.

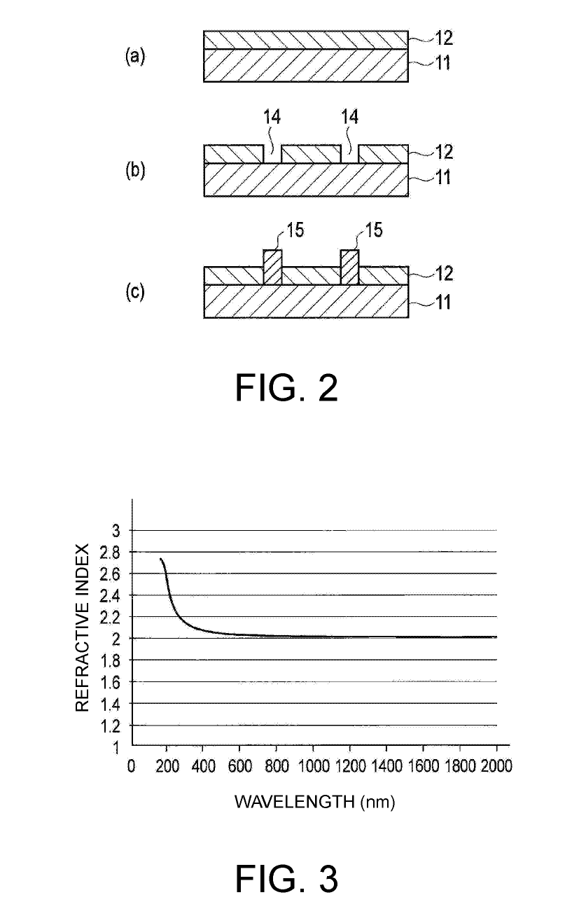

FIG. 2 shows diagrams showing a removal process according to laser processing on a thin dielectric film in a laser processing apparatus of Example 1 of the present invention. FIG. 2(a) shows the substrate 11 and the thin dielectric film 12. FIG. 2(b) shows a state in which laser processing is performed on the thin dielectric film 12 by the laser irradiation unit 2 shown in FIG. 1, and a groove 14 is formed in the thin dielectric film 12. FIG. 2(c) shows a state in which an electrode 15 is embedded in the groove 14 formed in the thin dielectric film 12.

FIG. 3 is a diagram showing a refractive index of silicon nitride used in the thin dielectric film 12 in the laser processing apparatus of Example 1 of the present invention with respect to a wavelength. As shown in FIG. 3, as the wavelength becomes shorter, the thin dielectric film 12 made of silicon nitride or the like has a higher refractive index and higher ratios of reflection and absorption with respect to transmission.

In a UV laser with a wavelength in a 300 nm-band, as described in the related art, a refractive index becomes higher, the reflectance becomes higher, and it is necessary to increase irradiation power. Thus, in the present invention, when the blue LD 3 with a wavelength in a 400 nm-band that is larger than a wavelength in a 300 nm-band is used, the reflectance is further reduced and the absorption is further increased. The blue LD 3 outputs blue light that has a wavelength in a 400 nm-band, a continuous wave (CW) of about 10 W, and has high brightness. The blue LD 3 with a wavelength of, for example, 405 nm or 450 nm, is used, and a core diameter is, for example, 100 μm.

Output light of the blue LD 3 is condensed by a condenser lens (not shown) and is output to a fiber 21.

The LD driver 4 corresponds to a semiconductor laser drive unit of the present invention and drives the blue LD 3 such that the blue LD 3 is caused to generate a CW laser beam.

The laser irradiation unit 2 includes the fiber 21, an optical system 22, a nozzle 23, a CCD camera 24, and an XYZ stage 25.

The fiber 21 guides a CW laser beam from the blue LD 3 to the optical system 22. The optical system 22 includes a condenser lens and the like, condenses a CW laser beam from the fiber 21, emits the beam to a processing target part of the thin dielectric film 12, and processes the thin dielectric film 12. The fiber 21 and the optical system 22 correspond to the irradiation unit of the present invention.

The inert gas 9 may be argon gas, nitrogen gas, and the like. The nozzle 23 corresponds to a gas spray unit of the present invention and sprays the inert gas 9 to the thin dielectric film 12 during laser irradiation.

The PC 6 includes an input operation unit such as a keyboard and a mouse (not shown), a CPU, and a memory. When the input operation unit is operated, speed information for moving the XYZ stage 25 at a predetermined speed and an XYZ direction movement instruction of the XYZ stage 25 are input and these are output to the XYZ motor controller 7.

The XYZ motor controller 7 outputs the speed information and the XYZ direction movement instruction from the PC 6 to the X motor driver 8a, the Y motor driver 8b, and the Z motor driver 8c. The fiber 21, the optical system 22, the nozzle 23, and the CCD camera 24 are placed on the XYZ stage 25.

The X motor driver 8a moves the XYZ stage 25 in the X direction at a predetermined speed based on the speed information and the XYZ direction movement instruction from the XYZ motor controller 7. The Y motor driver 8b moves the XYZ stage 25 in the Y direction at a predetermined speed based on the speed information and the XYZ direction movement instruction from the XYZ motor controller 7. The Z motor driver 8c moves the XYZ stage 25 in the Z direction at a predetermined speed based on the speed information and the XYZ direction movement instruction from the XYZ motor controller 7. Here, the predetermined speed is, for example, a speed of 3000 mm/min or lower.

That is, when the XYZ stage 25 on which the fiber 21, the optical system 22, the nozzle 23 and the CCD camera 24 are mounted moves in the XYZ directions at a predetermined speed, a laser beam of the blue LD 3 scans from the fiber 21 to the thin dielectric film 12, and laser processing is performed on an irradiation target part of the thin dielectric film 12.

The CCD camera 24 images the target part 1 including the thin dielectric film 12 to which a laser is emitted.

In the laser processing, laser heat is applied to the irradiation target part of the thin dielectric film 12 by the laser irradiation unit 2, and thereby the thin dielectric film 12 is processed. However, when a temperature difference between the temperature of the thin dielectric film 12 and the temperature of the substrate 11 is large, the thin dielectric film 12 cracks.

Thus, the heater 13 disposed below the substrate 11 heats the substrate 11 to about 300° C. or lower, and thereby a temperature difference between the temperature of the thin dielectric film 12 and the temperature of the substrate 11 is reduced and cracking of the thin dielectric film 12 is prevented.

In addition, when the inert gas 9 is sprayed (discharged) from the nozzle 23, abrupt heating of the thin dielectric film 12 can be alleviated, it is possible to prevent cracking of the thin dielectric film 12 and cracking of the substrate 11, and the residue can be blown away.

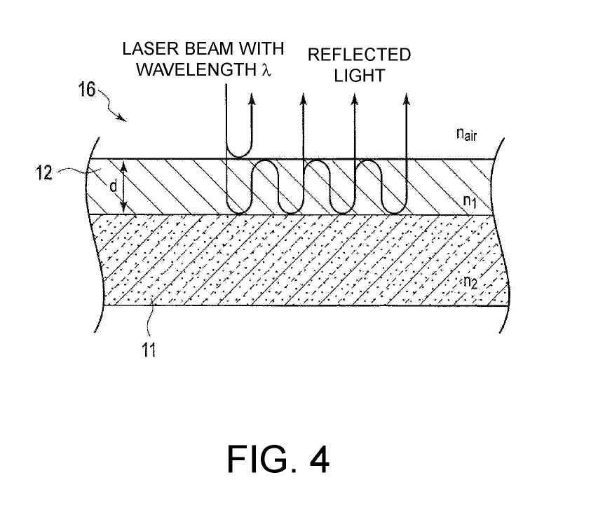

Next, a removal process of the thin dielectric film 12 will be described with reference to FIG. 4. Here, a wavelength of an incident laser beam is set as λ, a refractive index of the thin dielectric film 12 is set as n₁, and the thickness is set as d. When a refractive index n₂ of the substrate 11 is larger than a refractive index n₁ of the thin dielectric film 12, blue light which is a small amount of a laser light transmitted is reflected at the surface of the substrate 11.

However, when the thickness d of the thin dielectric film 12 and the wavelength λ, of incident light satisfy a condition of d=mλ/2 (m is a mode order), electric fields of incident light and reflected light overlap. Thus, light is multiply reflected in the thin dielectric film 12. Blue light is assumed to satisfy the above condition with respect to the thickness d of the thin dielectric film 12.

When a high energy laser beam is confined in the thin dielectric film 12, a high energy laser beam is absorbed into the thin dielectric film 12, and the thin dielectric film 12 can be removed.

In addition, as shown in FIG. 4, when a laser beam is perpendicularly incident from air 16 to the thin dielectric film 12, a surface reflectance Rref at that time is given by Formula (1).

Rref={(nₐᵢᵣ−n₁)/(nₐᵢᵣ+n₁)}² (1)

Here, nₐᵢᵣ is a refractive index of the air 16, and n₁ is a refractive index of the thin dielectric film 12.

Since nₐᵢᵣ is 1, the above formula becomes the following Formula (2).

Rref={(1−n₁)/(1+n₁)}² (2)

As can be understood from Formula (2), the surface reflectance Rref is a function of the refractive index n₁. Therefore, when the refractive index n₁ is large, the surface reflection increases.

Therefore, according to the laser processing apparatus of Example 1, when the blue LD 3 with a wavelength in a 400 nm-band is used and the LD driver 4 drives the blue LD 3, the blue LD 3 generates a CW laser beam, and the fiber 21 and the optical system lens 22 emit a CW laser beam to a processing target part of the thin dielectric film 12.

Then, the continuous wave laser beam is multiply reflected in the thin dielectric film 12 and the high energy laser beam is confined in the thin dielectric film 12.

Therefore, the high energy laser beam is absorbed into the thin dielectric film 12, and the thin dielectric film 12 can be removed. Therefore, the thin dielectric film 12 can be processed by a laser without cracking the substrate 11.

In addition, when the XYZ stage 25 moves in XYZ directions at a predetermined speed, a laser beam of the blue LD 3 scans from the fiber 21 to the thin dielectric film 12, and laser processing is performed on the thin dielectric film 12. Therefore, as shown in FIG. 2(b), the groove 14 can be formed in the thin dielectric film 12.

Here, the present invention is not limited to the laser processing apparatus of Example 1. In the laser processing apparatus of Example 1, when the XYZ stage 25 is moved at a predetermined speed with respect to the target part 1, laser processing is performed on the thin dielectric film 12.

For example, even if the target part 1 is moved at a predetermined speed with respect to the XYZ stage 25, laser processing can be performed on the thin dielectric film 12. In this case, the PC 6, the XYZ motor controller 7, the X motor driver 8a, the Y motor driver 8b, and the Z motor driver 8c may be provided on the side of the target part 1.

### INDUSTRIAL APPLICABILITY

The laser processing apparatus of the present invention can be applied to electronic devices, solar cells, and the like.

1. A laser processing apparatus comprising:
a thin dielectric film, formed on a surface of a substrate;
a blue semiconductor laser with a wavelength in a 400 nm-band;
a semiconductor laser drive unit, configured to drive the blue semiconductor laser such that a continuous wave laser beam is generated in the blue semiconductor laser; and
an irradiation unit, configured to emit the continuous wave laser beam generated by the blue semiconductor laser to a processing target part of the thin dielectric film.

2. The laser processing apparatus according to claim 1, comprising a movement mechanism, configured to move the irradiation unit at a predetermined speed with respect to the thin dielectric film or move the thin dielectric film at a predetermined speed with respect to the irradiation unit.

3. The laser processing apparatus according to claim 1, comprising
a gas spray unit, configured to spray an inert gas to the thin dielectric film during laser irradiation.

4. The laser processing apparatus according to claim 1, comprising
a heating unit, heats the substrate and configured to in contact with the substrate or disposed in the vicinity of the substrate.

5. The laser processing apparatus according to claim 1,
wherein the thin dielectric film is made of silicon nitride.

6. The laser processing apparatus according to claim 1,
wherein the thin dielectric film is made of silicon dioxide.

7. The laser processing apparatus according to claim 1,
wherein the thin dielectric film is made of titanium dioxide.
